(19) United States
(12) Patent Application Publication
(10) Pub. No.: US 2024/0355705 A1
(43) Pub. Date: Oct. 24, 2024

(54) POWER MODULE

(71) Applicants: Hyundai Motor Company, Seoul (KR); Kia Corporation, Seoul (KR)

(72) Inventor: Tae Hwa KIM, Hwaseong-Si (KR)

(73) Assignees: Hyundai Motor Company, Seoul (KR); Kia Corporation, Seoul (KR)

(21) Appl. No.: 18/389,496

(22) Filed: Nov. 14, 2023

(30) Foreign Application Priority Data
Apr. 20, 2023 (KR) 10-2023-0051899
Oct. 16, 2023 (KR) 10-2023-0137725

(51) Int. Cl. H01L 23/46

(52) U.S. Cl. CPC H01L 23/46; H01L 24/32; H01L 2224/32225

(57) ABSTRACT

A power module includes a first board including an insulation layer, a first metal layer disposed on a first side of the insulation layer, and a second metal layer disposed on a second side of the insulation layer opposed to the first side of the insulation layer, a semiconductor chip disposed on the first metal layer, a heat dissipation plate connected to the second metal layer in a first direction, a housing connected to the heat dissipation plate to form an integral cooling channel therein, and a connecting body made of a clad metal in which a first material, which is connected to the heat dissipation plate and is disposed to face an inside of the cooling channel, and a second material, which is connected to the housing and is different from the first material, overlap each other in the first direction.

### CROSS-REFERENCE TO RELATED APPLICATION

The present application claims priority to Korean Patent Application No. 10-2023-0051899, filed on Apr. 20, 2023, and Korean Patent Application No. 10-2023-0137725, filed on Oct. 16, 2023, the entire contents of which are incorporated herein for all purposes by this reference.

### BACKGROUND OF THE PRESENT DISCLOSURE

### Field of the Present Disclosure

The present disclosure relates to a power module including a cooling channel including a connecting structure using a clad metal.

### Description of Related Art

Recently, with increasing interest in the environment, the number of eco-friendly vehicles, each of which is provided with an electric motor as a power source, is increasing. The eco-friendly vehicles are also referred to as electric-powered vehicles. Representative examples of electric-powered vehicles may include an electric vehicle and a hybrid electric vehicle.

The electric-powered vehicle is provided with an inverter configured to convert DC power into AC power upon operation of a motor. The inverter is typically composed of one or more power modules each including a semiconductor chip configured to perform a switching function.

During operation of the power module, the semiconductor chip generates heat due to high voltage and high current. Because the operation of the power module is affected when the temperature of the power module increases due to the heat generated by the semiconductor chip, it is necessary to suppress heat generation for stable operation of the power module.

To suppress heat generation from the power module, various methods have been suggested. For example, there is a method in which a cooling channel is connected to a board and refrigerant flows through the cooling channel to improve cooling efficiency.

The method in which a cooling channel is connected to a board may be classified into an indirect cooling type and a direct cooling type. The indirect cooling method is performed such that a material such as a thermal interface material (TIM) is located between a board and a cooling channel to allow heat to be transmitted to the cooling channel from the board via the thermal interface material. Meanwhile, the direct cooling method is performed such that the cooling channel is directly coupled to the board to allow heat to be directly transmitted to the cooling channel from the board.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module which is configured to realize a connection structure to a cooling channel using a clad metal to improve cooling performance and to assure water tightness.

The objects of the present disclosure are not limited to the above-mentioned objects, and other objects of the present disclosure, which are not mentioned above, will be clearly understood from the following descriptions of exemplary embodiments

In accordance with the present disclosure, the above and other objects may be accomplished by the provision of a power module including a first board including an insulation layer, a first metal layer disposed on a first side of the insulation layer, and a second metal layer disposed on a second side of the insulation layer opposed to the first side of the insulation layer, a semiconductor chip disposed on the first metal layer, a heat dissipation plate connected to the second metal layer in a first direction, a housing connected to the heat dissipation plate to form an integrated cooling channel, and a connecting body made of a clad metal in which a first material, which is connected to the heat dissipation plate and is disposed to face an inside of the cooling channel, and a second material, which is connected to the housing and is different from the first material, overlap each other in the first direction.

For example, the heat dissipation plate may be at least a portion of the second metal layer.

For example, the heat dissipation plate may be formed independently of the second metal layer and may be coupled to the second metal layer.

The heat dissipation plate may be coupled to the second metal layer by an adhesive.

For example, the heat dissipation plate may extend further than the second metal layer in a second direction intersecting the first direction.

For example, the heat dissipation plate may include at least one projection which extends toward an inside of the cooling channel.

An end of the at least one projection extends to contact with an inner surface of the housing.

For example, the first material may be identical to that forming the heat dissipation plate, and the second material may be identical to that forming the housing.

For example, the housing may extend in a second direction intersecting the first direction from a position which is spaced in the first direction apart from one side of the heat dissipation plate that faces the cooling channel, and may be bent at first and second end portions thereof toward the heat dissipation plate in the first direction.

For example, the connecting body may be disposed between the heat dissipation plate and the first and second end portions of the housing in the second direction to connect the heat dissipation plate and the housing to each other.

For example, the connecting body may be constructed so that the second material is disposed so as not to be in contact with the heat dissipation plate.

For example, the connecting body may be constructed so that the first material extends in the second direction toward the heat dissipation plate from a portion thereof that overlaps the second material.

For example, the connecting body may be constructed so that the first material is disposed so as not to be in contact with the housing.

For example, the connecting body may be constructed so that the second material extends in the second direction toward the first and second end portions of the housing from a portion thereof that overlaps the first material.

For example, the first and second end portions of the housing, which are bent in the first direction, may be further bent in the second direction to be in contact with the heat dissipation plate.

For example, the connecting body may be constructed so that one of the first and second materials is bent along a surface of another of the first and second materials so that the first material and the second material overlap each other in the first and second directions, and is disposed at the heat dissipation plate and the first and second end portions of the housing to face an inside of the cooling channel.

For example, the power module according to an exemplary embodiment of the present disclosure may further include a second board, which includes an insulation layer, a first metal layer, a second metal layer, wherein the first metal layer of the second board is disposed on a first side of the insulation layer of the second board, and the second metal layer of the second board is disposed on a second side of the insulation layer of the second board opposed to the first side of the insulation layer of the second board, and wherein the second board is spaced from the first board in the first direction to be symmetrical with the first board, wherein the cooling channel is formed at at least one of the second metal layers of the first and second boards.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1, FIG. 2, and FIG. 3 are views for explaining connecting structures between a second metal layer and a heat dissipation plate according to various exemplary embodiments of the present disclosure;

FIG. 4, FIG. 5 and FIG. 6 are views for explaining detailed structures and dispositions of a connecting body according to various exemplary embodiments of the present disclosure:

FIG. 7 and FIG. 8 are views for explaining power modules of a double-sided cooling type according to various exemplary embodiments of the present disclosure; and

FIG. 9 and FIG. 10 are views for explaining how to connect the connecting body to the heat dissipation plate and the housing according to various exemplary embodiments of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Specific structural and functional descriptions of embodiments of the present disclosure included herein are only for illustrative purposes of the embodiments of the present disclosure. The present disclosure may be embodied in many different forms, without departing from the spirit and significant characteristics of the present disclosure. Therefore, the embodiments of the present disclosure are included only for illustrative purposes, and should not be construed as limiting the present disclosure.

Reference will now be made in detail to various embodiments of the present disclosure, specific examples of which are illustrated in the accompanying drawings and described below, since the embodiments of the present disclosure can be variously modified in many different forms. While the present disclosure will be described in conjunction with exemplary embodiments thereof, it is to be understood that the present description is not intended to limit the present disclosure to those exemplary embodiments of the present disclosure. On the other hand, the present disclosure is directed to cover not only the exemplary embodiments of the present disclosure, but also various alternatives, modifications, equivalents and other embodiments which may be included within the spirit and scope of the present disclosure as defined by the appended claims.

Unless otherwise defined, all terms including technical and scientific terms used herein include the same meanings as those commonly understood by one of ordinary skill in the art to which the present disclosure belongs. It will be further understood that terms, such as those defined in commonly used dictionaries, should be interpreted as including meanings consistent with their meanings in the context of the relevant art and the present disclosure, and are not to be interpreted in an idealized or overly formal sense unless so defined herein.

A description will now be provided in detail according to exemplary embodiments included herein, with reference to the accompanying drawings. For the sake of brevity of description with reference to the drawings, the same or equivalent components may be denoted by the same reference numbers, and a description thereof will not be repeated.

In general, suffixes such as “module” and “unit”, when used in the following description, may be used to refer to elements or components for easy preparation of the specification. The use of such suffixes herein is merely intended to facilitate the description of the specification, and the suffixes do not imply any special meaning or function.

Furthermore, in the following description of embodiments included herein, when it is decided that a detailed description of known functions or configurations related to the present disclosure would make the subject matter of the present disclosure unclear, such detailed description is omitted. The accompanying drawings are used to assist in easy understanding of various technical features, and it should be understood that the exemplary embodiments presented herein are not limited by the accompanying drawings. Accordingly, the present disclosure should be construed to extend to any alterations, equivalents, and substitutes, in addition to those which are particularly set out in the accompanying drawings.

It will be understood that, although the terms “first,” “second,” etc. may be used herein to describe various elements, these elements should not be construed as being limited by these terms. These terms are only used to distinguish one element from another element.

It will be understood that when an element is referred to as being “coupled” or “connected” to another element, it may be directly coupled or connected to the other element, or intervening elements may be present therebetween. In contrast, it should be understood that when an element is referred to as being “directly coupled” or “directly connected” to another element, there are no intervening elements present.

As used herein, the singular forms “a,” “an” and “the” are intended to include the plural forms as well, unless the context clearly indicates otherwise.

It will be further understood that the terms “comprise”, “include”, “have”, etc. When used in the present specification specify the presence of stated features, integers, steps, operations, elements, components, and/or combinations thereof, but do not preclude the presence or addition of one or more other features, integers, steps, operations, elements, components, and/or combinations thereof.

Embodiments of the present disclosure suggest a power module which is provided with a connection structure to a cooling channel via a clad metal to efficiently radiate heat generated by the power module and to assure water tightness of the cooling channel.

The term “clad metal” as used herein means a complex material in which different kinds of metals are integrally coupled to each other. by use of the clad metal, it is possible to obtain all of the advantages of the metals included in the clad metal. The clad metal may be manufactured through hot rolling, explosive welding, resistance seam welding or the like.

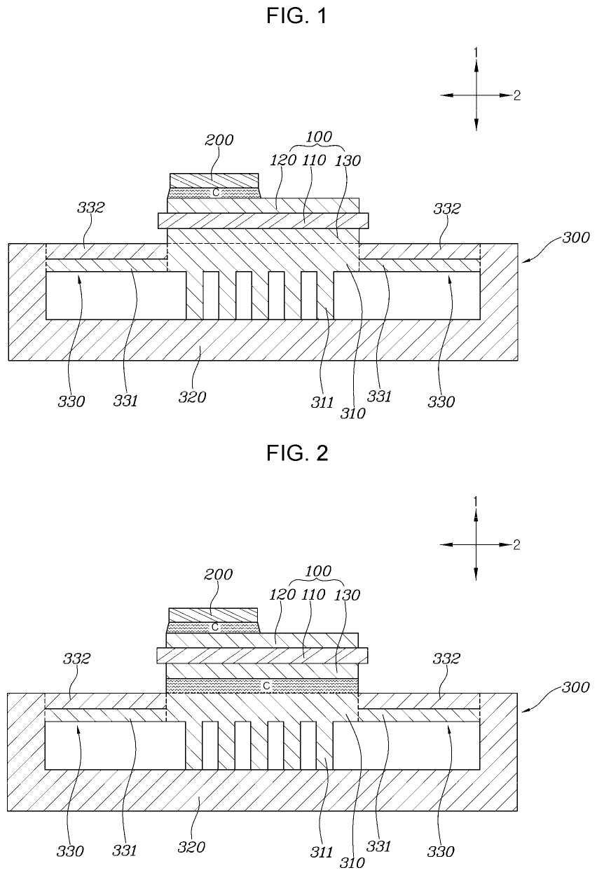

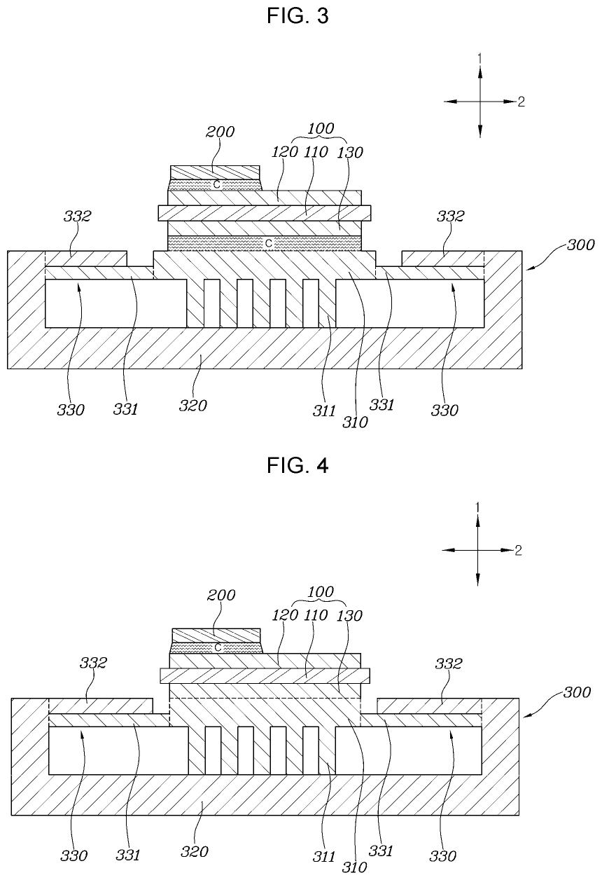

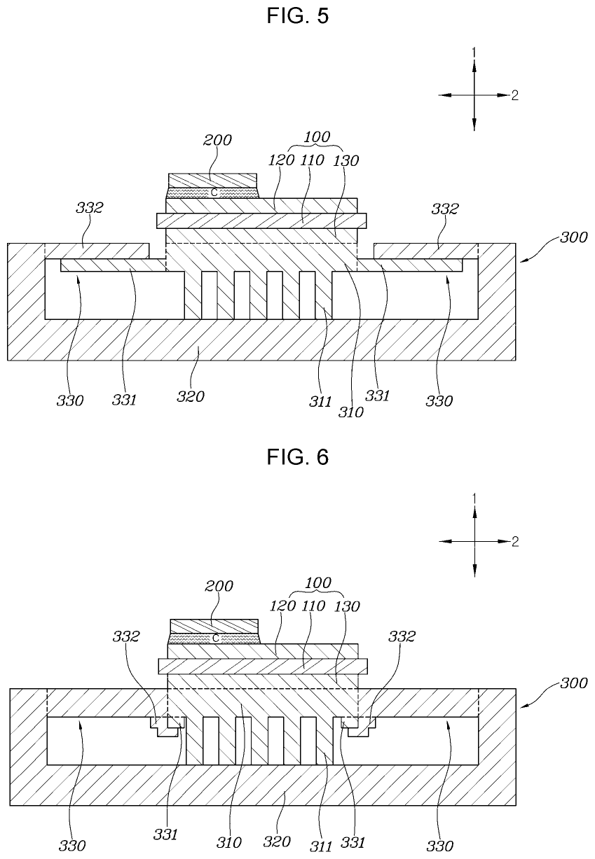

In embodiments of the present disclosure, a power module may be embodied as a structure in which a pair of boards are opposed to each other with a semiconductor chip interposed therebetween or a structure in which a semiconductor chip is disposed on a single board. Accordingly, FIG. 1, FIG. 2, FIG. 3, FIG. 4, FIG. 5 and FIG. 6 show a structure in which a pair of boards are opposed to each other but illustration of one of the pair of boards is omitted or a structure in which a semiconductor chip is disposed on a single board.

In the following description, although a first direction may be understood to be a vertical direction based on the drawings and a second direction intersecting the first direction may be understood to be a lateral direction based on the drawings, these are merely for convenience of explanation. In actual realization of the power module, the vertical direction and the lateral direction may be changed depending on disposition of the power module.

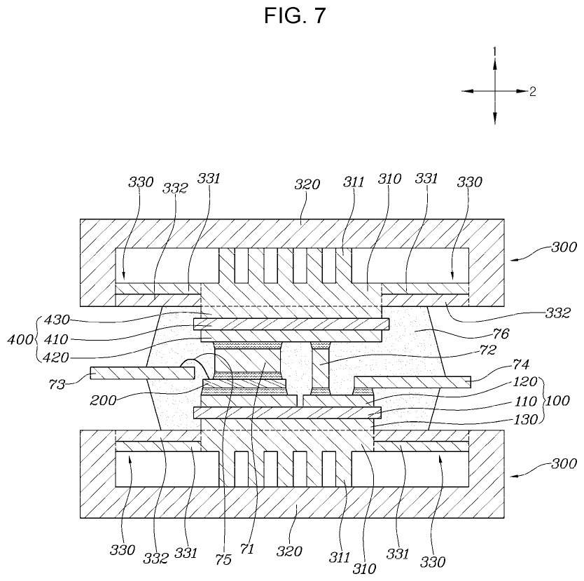

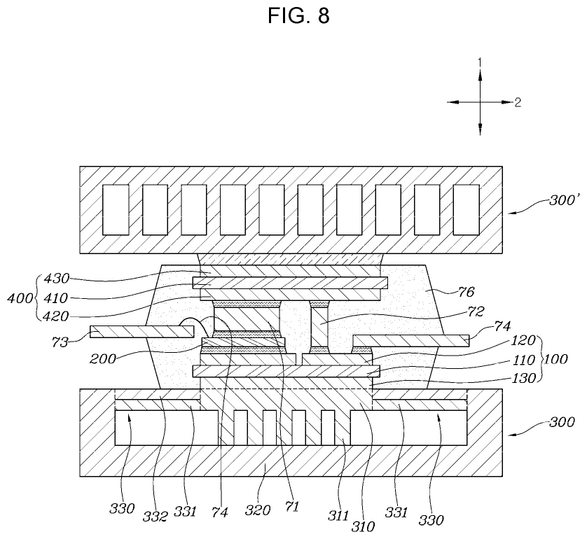

Hereinafter, power modules according to various exemplary embodiments of the present disclosure will be described with reference to FIG. 1, FIG. 2, FIG. 3, FIG. 4, FIG. 5, FIG. 6, FIG. 7, and FIG. 8.

First, the components of the power modules according to various exemplary embodiments of the present disclosure and the connection relationships therebetween will be described with reference to FIG. 1, FIG. 2, and FIG. 3.

FIG. 1, FIG. 2, and FIG. 3 are views for explaining the connection structures between a board and a cooling channel according to various exemplary embodiments of the present disclosure.

FIG. 1 illustrates an exemplary embodiment of the present disclosure in which the cooling channel is integrally formed with the board. FIGS. 2 and 3 illustrate another exemplary embodiment in which the cooling channel is formed independently of the board.

Referring to FIG. 1, FIG. 2, and FIG. 3, the power module according to each of embodiments of the present disclosure may include a first board 100, a semiconductor chip 200, a heat dissipation plate 310, a housing 320, and a connecting body 330. Although FIG. 1, FIG. 2, and FIG. 3 mainly show the components associated with the power module according to the exemplary embodiments of the present disclosure, it goes without saying that the power module may be embodied to include more or fewer components. Hereinafter, the components will be described in detail.

The first board 100 may include an insulation layer 110, a first metal layer 120 disposed on one side of the insulation layer 110, and a second metal layer 130 disposed on the other side of the insulation layer 110 opposed to the one side of the insulation layer 110.

The insulation layer 100 may be provided for electrical isolation between the inside and the outside of the power module, and may be embodied by, for example, ceramic.

The first metal layer 120 may be disposed inside the power module for electrical connection to the interior of the power module, and may be provided with a pattern for electrical connection to the interior of the power module.

The second metal layer 130 is configured to radiate heat, which is generated by the semiconductor chip 200 in the power module, to the outside through heat exchange with the outside thereof, cooling the power module. To the present end, the second metal layer 130 may be disposed on the external side of the power module.

The first metal layer 120 and the second metal layer 130 may be made of, for example, copper including excellent thermal conductivity. The first board 100 may be provided by use of AMB (Active Metal Brazed (AMB) or Direct Bonded Copper (DBC)).

The semiconductor chip 200 may be disposed on the first metal layer 120, and may be bonded to the first metal layer 120 via an adhesive C.

The semiconductor chip 200 may be turned ON/OFF in response to a switching signal, and electrical connection between the upper side and the lower side of the semiconductor chip 200 may be determined in accordance with ON/OFF status of the semiconductor chip 200.

The semiconductor chip 200 may be embodied as a switching device, for example, an insulated gate bipolar transistor (IGBT), a metal-oxide-semiconductor field-effect transistor (MOSFET) or the like, and may be made of silicon (Si), silicon carbide (SiC) or the like.

The heat dissipation plate 310 and the housing 320 may be connected to each other via the connecting body 330, forming the integral cooling channel 300.

The heat dissipation plate 310 may be connected to the second metal layer 130 in the first direction to receive heat from the first board 100.

Referring to FIG. 1, the heat dissipation plate 310 may be integrally formed with the second metal layer 130 to form at least a portion of the second metal layer 130. In other words, the second metal layer 130 itself is configured as the heat dissipation plate 310 to form a portion of the cooling channel 300.

Referring to FIG. 2, the heat dissipation plate 310 may be formed independently of the second metal layer 130 and may be coupled to the second metal layer 130, unlike the structure shown in FIG. 1. In the instant case, the coupling between the heat dissipation plate 310 and the second metal layer 130 may be implemented via an adhesive C, welding or the like.

In the case in which the heat dissipation plate 310 is integrally formed with the second metal layer 130, the power module may be manufactured so that the connecting body 330 is coupled to the first board 100 and the housing 320 is then coupled to the connecting body 330. In the case in which the heat dissipation plate 310 is formed independently of the second metal layer 130, the power module may be manufactured so that the first board 100 and the cooling channel 300 are separately provided and then coupled to each other.

The heat dissipation plate 310 may be made of the same material as the second metal layer 130. For example, the second metal layer 130 and the heat dissipation 310 are both made of copper (Cu) including excellent thermal conductivity for effective heat dissipation.

The heat dissipation plate 310 may include at least one projection 311, which extends toward the inside of the cooling channel 300 in the first direction. In other words, the heat dissipation plate 310 may be provided with a fin-shaped structure. Because the heat dissipation plate 310 is provided with the projection 311, the surface area required for heat dissipation may be increased, and thus the cooling performance of the power module may be improved.

In an exemplary embodiment of the present disclosure, ends of the at least one projection 311 may contact with an inner surface of the housing 320.

Referring to FIG. 3, the heat dissipation plate 310 may extend farther than the second metal layer 130 in the second direction thereof. In the instant case, because the surface area of the heat dissipation plate 310, which is exposed to the cooling channel 300, is increased, the cooling performance of the power module may be improved.

The housing 320 may form the lateral surface of the cooling channel 300 and at least a portion of the upper and lower surfaces of the cooling channel 300, and may be integrally connected to the heat dissipation plate 310 and the connecting body 330 to form the hermetic cooling channel 300. Because the housing 320 has less influence on the heat transfer path, the housing 320 may be made of a material, which is inferior to the heat dissipation plate 310 in thermal conductivity but is relatively light and inexpensive.

The connecting body 330 may be made of a clad metal in which a first material 331, which is connected to the heat dissipation plate 310, and a second material 332, which is connected to the housing 320 and is different from the first material 331, overlap each other.

The first material 331 may be a material which is easily coupled to the heat dissipation plate 310 and the second material 332 may be a material which is easily coupled to the housing 320.

Because different kinds of metals, such as copper (Cu) and aluminum (Al), have different chemical properties, there is a difficulty in directly coupling the two metals to each other via welding, an adhesive or the like. Accordingly, by causing the adjacent portions of the power module to be easily coupled to each other by interposition of the clad metal in which different kinds of materials are integrally coupled to each other, it is possible to obtain the integral structure in which the components of the power module are integrally coupled to each other.

The first material 331, which is connected to the heat dissipation plate 310 and is closely related to heat dissipation, may be made of a material including excellent thermal conductivity, and the second material 332, which is less related to heat dissipation, may be selected based on weight and cost.

Here, the first material 331 may be disposed to face the inside of the cooling channel 300. In the case in which the first material 331 is the same as the material forming the heat dissipation plate 310, the first material 331 may be advantageously coupled to the heat dissipation plate 310, and the surface area of the heat dissipation plate 310 in the cooling channel 300 may be substantially increased, improving the cooling performance of the power module.

Because the cooling channel 300 is constructed by connecting the heat dissipation plate 310 to the housing 320 via the connecting body 330 composed of a clad metal, it is possible to assure water-tightness of the cooling channel 300 even without interposing an additional sealing member, such as a gasket, an O-ring or the like. Furthermore, because the connecting body 330, which is made of metal including a thermal conductivity higher than a general sealing member, forms a portion of the cooling channel 300, it is also possible to improve cooling performance.

Furthermore, because the heat dissipation plate 310 and the housing 320, which are made of different kinds of metals, are easily coupled to each other via the connecting body 330, it is possible to alleviate restrictions on selection of the material of the housing 320 which are caused in improvement of coupling quality.

Hereinafter, the detailed structures of the housing 320 and the connecting body 330 will be described with reference to FIG. 4, FIG. 5 and FIG. 6.

FIG. 4, FIG. 5 and FIG. 6 are views explaining the detailed structures and the dispositions of the connecting bodies according to various exemplary embodiments of the present disclosure.

The connecting body 330, which has been described with reference to FIG. 1, FIG. 2, and FIG. 3, may be applied in various fashions depending on the shape of the housing 320.

Referring to FIG. 4, for example, the housing 320 may be shaped in such a fashion as to extend in the second direction from a position, which is spaced from one surface of the heat dissipation plate 310 that faces the cooling channel 300, and then to be bent at the two end portions thereof toward the heat dissipation plate 310 in the first direction.

In the instant case, the connecting body 330 may be disposed between the end portion of the heat dissipation plate 310 and the end portion of the housing 320 to connect the heat dissipation plate 310 and the housing 320 to each other. Here, the connecting body 330 may be constructed so that the second material 332 is not in contact with the heat dissipation plate 310. To the present end, the first material 331 may extend toward the heat dissipation plate 310 from the portion thereof that overlaps the second material 332, in the second direction thereof.

Referring to FIG. 5 the connecting body 330 may be constructed so that the first material 331 is not in contact with the housing 320. To the present end, the second material 332 may extend toward the housing 320 from the portion thereof that overlaps the first material 331, in the second direction thereof.

Because the first material 331 is not in contact with the housing 320 while the second material 332 is not contact with the heat dissipation plate 310, it is possible to relatively reduce formation of the interface at which different kinds of materials are in contact with each other.

Referring to FIG. 6, the housing 320 may be constructed to be further bent in the second direction so that the two bent end portions thereof are in contact with the heat dissipation plate 310.

In the instant case, the connecting body 330 may be constructed so that one of the first material 331 and the second material 332 is bent along the surface of the other of the first material 331 and the second material 332 so that the first material 331 and the second material 332 overlap each other in the first direction as well as in the second direction thereof. The connecting body 330, which is constructed to include the present shape, may be disposed at the heat dissipation plate 310 and the two end portions of the housing 320 to face the inside of the cooling channel 300.

Hereinafter, the case in which the power module according to the exemplary embodiments of the present disclosure, which is described with reference to FIGS. 1 to 6, is constructed into a double-sided cooling type will be described.

FIG. 7 and FIG. 8 are views explaining embodiments of the present disclosure which are constructed into a double-sided cooling type.

The exemplary embodiments of the present disclosure may further include a second board 400, which is spaced from the first board 100 in the first direction to be symmetrical with the first board 100. Similar to the first board 100, the second board 400 may include an insulation layer 410, a first metal layer 420 disposed on one side of the insulation layer 410, and a second metal layer 430 disposed on the other side of the insulation layer 410 opposed to the one side of the insulation layer 410. In this case, the semiconductor chip 200 may be disposed between the first and second boards 100 and 400. The semiconductor chip 200 may be connected to the second board 400 by a chip spacer 71 and the first and second boards 100 and 400 may be connected by a via spacer 72. In addition, the power module may include a signal lead 73 and a power lead 74 for electrical connection with the outside. The signal lead 73 may be connected to the semiconductor chip 200 by a wire 75 and the power lead 74 may be bonded to the first board 100. Meanwhile, the first and second boards 100 and 400, the semiconductor chip 200, the chip spacer 71, the via spacer 72, the signal lead 73 and the power lead 74 may be at least partially wrapped by a filling material 76 for example EMC (Epoxy Molding Compound).

In the exemplary embodiment of the present disclosure, the cooling channel 300 may be formed at at least one of the second metal layers 130 and 430 of the first and second boards 100 and 400.

Referring to FIG. 7, for example, the cooling channels 300 according to an exemplary embodiment of the present disclosure may be formed both at the second metal layer 130 of the first board 100 and at the second metal layer 430 of the second board 400.

Unlike the above embodiment, referring to FIG. 8, the cooling channel 300 according to an exemplary embodiment of the present disclosure may be formed at the second metal layer 130 of the first board 100 but a cooling channel 300′, which is embodied by a single material, may be formed at the second metal layer 430 of the second board 100.

Unlike the exemplary embodiments shown in FIGS. 7 and 8, a cooling channel may be formed at one of the second metal layers 130 and 430 of the first and second boards 100 and 400 via a sealing member such as a gasket or the like.

Hereinafter, how to connect the connecting body made of clad metal to the heat dissipation plate and the housing will be described in detail.

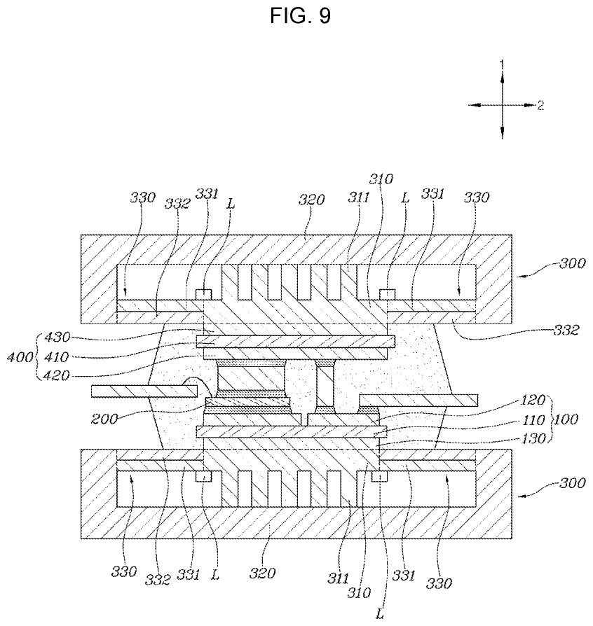

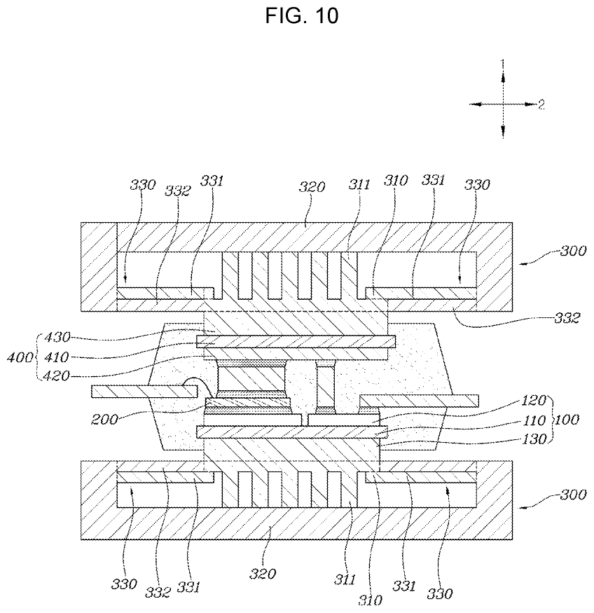

FIGS. 9 and 10 are views for explaining how to connect the connecting body to the heat dissipation plate and the housing according to various exemplary embodiments of the present disclosure.

Referring to FIG. 9, in the power module according to one embodiment of the present disclosure, the connecting body 330 and the heat dissipation plate 310 may be connected to each other via an intermediate metal L, which is coupled at one end thereof to the first material 331 of the connecting body 330 and at the other end thereof to the heat dissipation plate 310 in the cooling channel 300.

Because the intermediate metal L covers from one side of the connecting body 330 to one side of the heat dissipation plate 310, the connecting body 330 and the heat dissipation plate 310 may be connected to each other via the intermediate metal L, thereby improving water-tightness of the cooling channel 300.

In this embodiment, the intermediate metal L may be coupled to the connecting body 330 and the heat dissipation plate 310 through welding. Here, because the connecting body 330 is coupled to the heat dissipation plate 310 by welding each of the connecting body 330 and the heat dissipation plate 310 to the intermediate metal L rather than directly coupling the connecting body 330 to the heat dissipation plate 310, it is possible to perform welding using low energy and thus to reduce cost for connection between components in a production process.

Referring to FIG. 10, the connecting body 330 may be constructed such that the first material 331 may extend in the second direction at an inner side of the cooling channel 300 which is internally located than the heat dissipation plate 310 in the first direction such that a least a portion of the first material 331 overlaps the heat dissipation plate 310 in the first direction. Consequently, the at least a portion of the first material 331, which overlaps the heat dissipation plate 310, may be coupled and thus connected to the heat dissipation plate 310.

In this way, because the first material 331 is coupled to the heat dissipation plate 310 at the area in which the first material 331 overlaps the heat dissipation plate 310 in the first direction, the gap between the connecting body 330 and the second material 332 is covered by the first material 331, thereby improving water-tightness of the cooling channel 300. Consequently, even when a tolerance is generated between the connecting body 330 and the heat dissipation plate 310, it is possible to assure water-tightness of the cooling channel 300 and thus to alleviate difficulty in a process due to tolerance management or the like.

More specifically, at one end of the connecting body 330, the first material 331 may be coupled to the surface of the heat dissipation plate 310 that faces the inside of the cooling channel 300 while being in contact with the surface, through welding, and, at the other end of the connecting body 330, the second material 332 may be coupled to the portion of the housing 320 that is bent in the first direction while being in contact with the portion, through welding.

In this case, the second material 332 may not be coupled to the heat dissipating plate 310 at the one end of the connecting body 330, and the first material 331 may not be coupled to the housing 320 at the other end of the connecting body 330. However, it is possible to assure water-tightness of the cooling channel 300, regardless of whether or not the second material 332 is coupled to the heat dissipation plate 310 or whether or not the first material 331 is coupled to the housing 320.

As is apparent from the above description, according the various embodiments of the present disclosure, because the board and the cooling channel are directly coupled to each other, it is possible to improve the cooling performance of the power module.

Furthermore, because the connection structure is embodied by the clad metal, it is possible to improve the cooling performance of the power module while improving the water-tightness of the cooling channel.

Furthermore, because the cooling performance and the water tightness of the power module are improved, it is easy to manufacture and manage the power module. Consequently, because the operational performance of the power module is improved, it is possible to increase the output density of an inverter to which the power module is applied.

The effects obtained by the present disclosure are not limited to the above-mentioned effects, and other effects of the present disclosure, which are not mentioned above, will be clearly understood from the following descriptions by one of ordinary skill in the art to which the present disclosure belongs.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
a first board including an insulation layer, a first metal layer disposed on a first side of the insulation layer, and a second metal layer disposed on a second side of the insulation layer opposed to the first side of the insulation layer;
a semiconductor chip disposed on the first metal layer;
a heat dissipation plate connected to the second metal layer in a first direction thereof;
a housing connected to the heat dissipation plate to form an integral cooling channel therein; and
a connecting body made of a clad metal in which a first material, which is connected to the heat dissipation plate and is disposed to face an inside of the cooling channel, and a second material, which is connected to the housing and is different from the first material, overlap each other in the first direction.

2. The power module of claim 1, wherein the heat dissipation plate is at least a portion of the second metal layer.

3. The power module of claim 1, wherein the heat dissipation plate is formed independently of the second metal layer and is coupled to the second metal layer.

4. The power module of claim 3, wherein the heat dissipation plate is coupled to the second metal layer by an adhesive.

5. The power module of claim 1, wherein the heat dissipation plate extends farther than the second metal layer in a second direction intersecting the first direction.

6. The power module of claim 1, wherein the heat dissipation plate includes at least one projection which extends toward an inside of the cooling channel.

7. The power module of claim 6, wherein an end of the at least one projection extends to contact an inner surface of the housing.

8. The power module of claim 1, wherein the first material is identical to a material forming the heat dissipation plate, and the second material is identical to a material forming the housing.

9. The power module of claim 1, wherein the housing extends in a second direction intersecting the first direction from a position which is spaced in the first direction apart from one side of the heat dissipation plate that faces the cooling channel, and is bent at first and second end portions thereof toward the heat dissipation plate in the first direction.

10. The power module of claim 9, wherein the connecting body is disposed between the heat dissipation plate and the first and second end portions of the housing in the second direction to connect the heat dissipation plate and the housing to each other.

11. The power module of claim 10, wherein the second material of the connecting body is disposed so as not to be in contact with the heat dissipation plate.

12. The power module of claim 11, wherein the first material of the connecting body extends in the second direction toward the heat dissipation plate from a portion thereof that overlaps the second material.

13. The power module of claim 12, wherein the first material of the connecting body is disposed so as not to be in contact with the housing.

14. The power module of claim 13, wherein the second material of the connecting body extends in the second direction toward the first and second end portions of the housing from a portion thereof that overlaps the first material.

15. The power module of claim 8, wherein the connecting body and the heat dissipation plate are connected to each other via an intermediate metal which is coupled at one end thereof to the first material and at a remaining end thereof to the heat dissipating plate.

16. The power module of claim 8, wherein the first material of the connecting body extends in the second direction at an inner side of the cooling channel which is internally located than the heat dissipation plate in the first direction such that a least a portion of the first material overlaps the heat dissipation plate in the first direction, and the at least a portion of the first material, which overlaps the heat dissipation plate, is coupled and thus connected to the heat dissipation plate.

17. The power module of claim 9, wherein the first and second end portions of the housing, which are bent in the first direction, are further bent in the second direction to be in contact with the heat dissipation plate.

18. The power module of claim 17 wherein one of the first and second materials of the connecting body is bent along a surface of another of the first and second materials so that the first material and the second material overlap each other in the first and second directions, and is disposed at the heat dissipation plate and the first and second end portions of the housing to face an inside of the cooling channel.

19. The power module of claim 1, further including:
a second board, which includes an insulation layer, a first metal layer and a second metal layer, wherein the first metal layer of the second board is disposed on a first side of the insulation layer of the second board, and the second metal layer of the second board is disposed on a second side of the insulation layer of the second board opposed to the first side of the insulation layer of the second board, and wherein the second board is spaced from the first board in the first direction to be symmetrical with the first board,
wherein the cooling channel is formed at at least one of the second metal layers of the first and second boards.
